(19) United States
(12) Patent Application Publication
(10) Pub. No.: US 2014/0226298 A1
(43) Pub. Date: Aug. 14, 2014

(54) APPARATUS FOR SECURELY DISPLAYING AN ELECTRONIC DEVICE

(71) Applicant: Palmer Distributors Incorporated, St. Clair Shores, MI (US)

(72) Inventors: James Palmer, Grosse Pointe Farms, MI (US); Kevin Elnicky, Ortonville, MI (US)

(73) Assignee: Palmer Distributors Incorporated, St. Claire Shores, MI (US)

(21) Appl. No.: 14/180,196

(22) Filed: Feb. 13, 2014

Related U.S. Application Data
(60) Provisional application No. 61/764,360, filed on Feb. 13, 2013.
(60) Provisional application No. 61/868,804, filed on Aug. 22, 2013.

(51) Int. Cl. H05K 5/02; E05B 73/00; A47F 7/024

(52) U.S. Cl. CPC H05K 5/0208; A47F 7/024; E05B 73/00
USPC 361/807; 29/428; 248/551

(57) ABSTRACT

An apparatus for securely displaying an electronic device is disclosed. The apparatus comprises a support, a frame coupled to the support, a case, and a securing device removably coupled to the frame. The frame has a frame base and at least one retaining feature coupled to the frame base with at least one of the retaining feature and the frame base defining a frame slot. The case is formed of a polymeric material and has an opening for at least partially encapsulating the electronic device while permitting the face of the electronic device to be exposed through the opening. The securing device has a securing base and a locking feature selectively mounted to the securing base with the locking feature at least partially defining a securing slot. The frame slot and the securing slot cooperate to securely retain the case to the frame for preventing theft of the electronic device.

### CROSS REFERENCE TO RELATED APPLICATIONS

The subject application claims priority to and all of the benefits of U.S. Provisional Application Ser. No. 61/764,360, filed Feb. 13, 2013, and U.S. Provisional Application Ser. No. 61/868,804, filed Aug. 22, 2013. The contents of U.S. Provisional Application Ser. Nos. 61/764,360 and 61/868,804 are expressly incorporated herein in their entirety.

### FIELD OF THE DISCLOSURE

The subject disclosure relates generally to an apparatus for securely displaying an electronic device.

### BACKGROUND

Electronic devices such as cellular phones and tablet computers are displayed in retail stores, trade shows, and/or the like so that potential customers can hold, feel, and view the devices. One way of displaying the electronic device is to place the electronic device in an apparatus, such as a docking station, and then coupling the apparatus to a table top, a counter top, a wall, and the like. In some instances, however, the electronic device may not be securely retained by the docking station, and may therefore be susceptible to theft. Accordingly, there is a need for an apparatus for securely displaying an electronic device where the electronic device cannot be easily removed from the apparatus.

### SUMMARY

An apparatus for securely displaying an electronic device is disclosed herein. The apparatus comprises a support, a frame coupled to the support, a case, and a securing device removably coupled to the frame. The frame has a frame base and at least one retaining feature coupled to the frame base with at least one of the retaining feature and the frame base defining a frame slot. The case is formed of a polymeric material and has an opening for at least partially encapsulating the electronic device while permitting a face of the electronic device to be exposed through the opening. The securing device has a securing base and a locking feature selectively mounted to the securing base with the locking feature at least partially defining a securing slot. The frame slot and the securing slot cooperate to securely retain the case to the frame for preventing theft of the electronic device.

### BRIEF DESCRIPTION OF THE DRAWINGS

Advantages of the present disclosure will be readily appreciated as the same becomes better understood by reference to the following detailed description when considered in connection with the accompanying drawings.

FIG. 1 is a perspective view of an example of an assembly comprising an embodiment of an apparatus for securely displaying an electronic device.

FIG. 2 is a perspective view of the apparatus of FIG. 1.

FIG. 3 is a perspective view of a frame and a securing device removably coupled to the frame, where the frame and the securing device are components of the apparatus depicted in FIG. 2.

FIG. 4 is a semi-schematic, bottom view of the frame and the securing device removably coupled to the frame, where the frame and the securing device are components of the apparatus depicted in FIG. 2.

FIG. 5 is a perspective view of a case, which is another component of the apparatus depicted in FIG. 2.

FIG. 6 is a cross-sectional view of the apparatus depicted in FIG. 2 taken along line 6-6 in FIG. 2.

FIG. 7 is a side view of the apparatus of FIG. 2.

FIG. 8 is a side view of another embodiment of an apparatus for securely displaying an electronic device.

FIG. 9 is a side view of still another embodiment of an apparatus for securely displaying an electronic device.

FIG. 10 is a side view of another embodiment of an apparatus for securely displaying an electronic device.

FIG. 11 is an exploded, side view of the embodiment of the apparatus depicted in FIG. 10.

FIG. 12 is a side view of yet another embodiment of an apparatus for securely displaying an electronic device.

FIG. 13 is an exploded, side view of the embodiment of the apparatus depicted in FIG. 12.

FIGS. 14A through 14C, together, depict an example of a securely displaying an electronic device utilizing the embodiment of the apparatus depicted in FIG. 2, where FIG. 14A illustrates at least partially encapsulating the electronic device in the case, FIG. 14B illustrates inserting a portion of the case with the electronic device into a frame slot, and FIG. 14C depicts positioning the securing device about the case such that a second portion of the case with the electronic device is disposed within a securing slot.

FIG. 15 is a perspective view of another example of an assembly comprising an embodiment of an apparatus for displaying two electronic devices.

FIG. 16 is an exploded, perspective view of the apparatus depicted in FIG. 15.

FIG. 17 is a cross-sectional view of the assembly depicted in FIG. 15 taken along line 17-17 in FIG. 15.

FIG. 18 is a perspective view of another embodiment of an apparatus for securely displaying an electronic device.

FIG. 19 is a perspective view of still another embodiment of an apparatus for securely displaying an electronic device.

FIG. 20 is another perspective view of the apparatus depicted in FIG. 19.

FIG. 21 is a perspective view of yet another embodiment of an apparatus for securely displaying an electronic device.

FIG. 22 is a perspective view of another embodiment of the apparatus for securely displaying an electronic device.

FIG. 23 is a perspective view of the embodiment of the apparatus depicted in FIG. 15 comprising a tag holder.

FIG. 24 is another perspective view of the apparatus depicted in FIG. 23.

FIG. 25 is a perspective view of yet another example of an assembly including an embodiment of the apparatus for securely displaying an electronic device.

FIG. 26 is a perspective view of the apparatus depicted in FIG. 25.

FIG. 27 is a perspective view of another embodiment of the apparatus for securely displaying an electronic device.

FIG. 28 is a perspective view of still another embodiment of an apparatus for securely displaying an electronic device.

FIGS. 29A through 29C together, depict an example of a securely displaying an electronic device utilizing the embodiment of the apparatus depicted in FIG. 15, where FIG. 29A illustrates at least partially encapsulating the electronic device in the case, FIG. 29B illustrates inserting a portion of the case with the electronic device into a frame slot, and FIG. 29C depicts positioning the securing device about the case such that a second portion of the case with the electronic device is disposed within a securing slot.

### DETAILED DESCRIPTION

The apparatus as disclosed herein is designed to securely display an electronic device. The apparatus may be used to display the electronic device, for example, in a store, at a tradeshow, in a shop, or in another facility where electronic devices are typically bought and/or sold. The apparatus may also be used on other environments or facilities that are not involved in buying and selling electronic devices such as in a hospital, a stadium, a museum, etc. Non-limiting examples of electronic devices that may be securely displayed utilizing the apparatus of the present disclosure include smartphones (such as an iPhone® available from Apple Inc. (Cupertino, Calif.)) and tablet computers (such as an iPad® also available from Apple Inc.). Typically, the apparatus is designed to securely display a particular type and brand of the electronic device. It is to be appreciated, however, that the apparatus may be re-designed to securely display another electronic device. For instance, the apparatus may be re-designed to securely display mp3 players (such as an iPod® available from Apple Inc.), cellular phones, electronic book readers (such as a Nook® available from Barnes and Noble (New York City, N.Y.), and/or other electronic devices.

The apparatus is also pre-designed to be coupled, attached, and/or connected to a surface inside the store, shop, tradeshow, etc. Non-limiting examples of surfaces to which the apparatus may be coupled, attached, and/or connected include walls, floors, table tops, a counter tops, shelves, furniture, and/or the like.

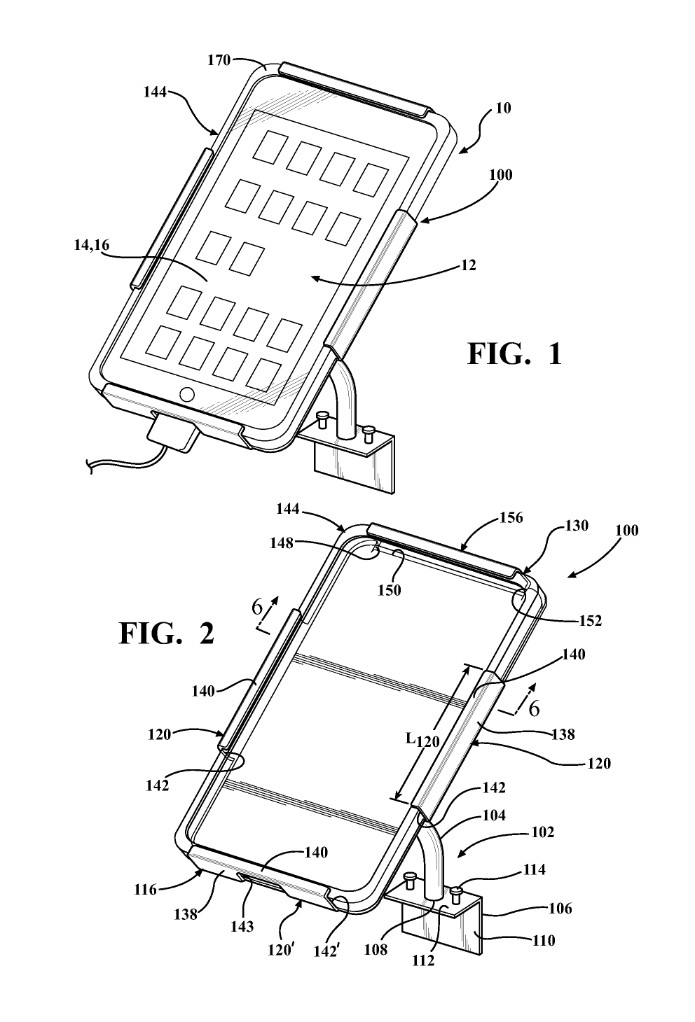

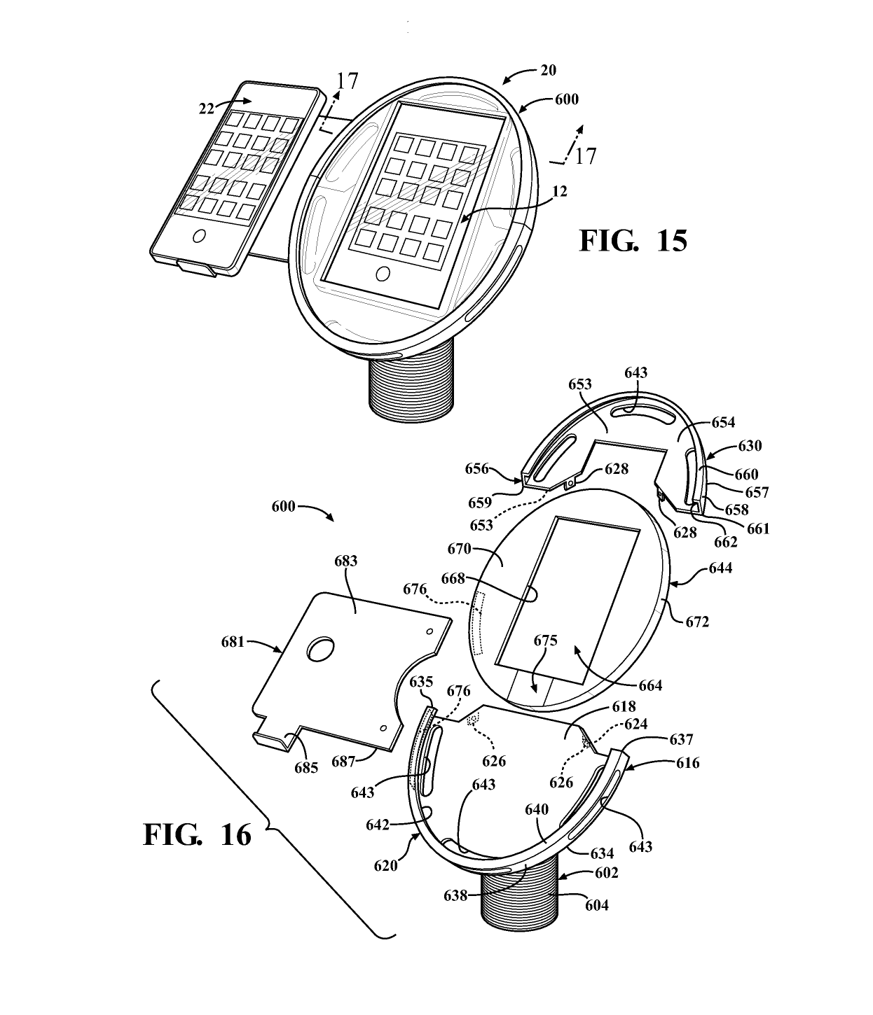

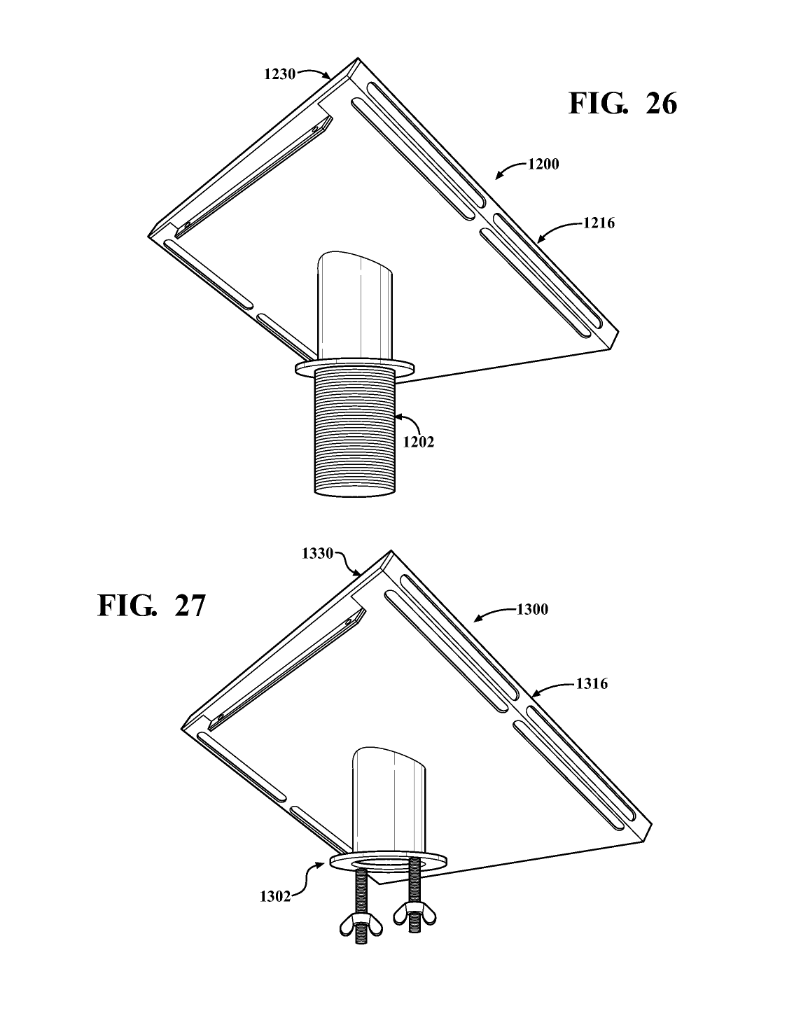

In each of the embodiments described below, the apparatus is designed to securely display an electronic device. In some embodiments, such as those described with reference to FIGS. 1-14, 19-22, and 25-28, the apparatus is designed to securely display one electronic device. In other embodiments, such as those described with reference to FIGS. 15, 16, 18, 23, and 24, the apparatus is designed to securely display one electronic device and is further designed to display a second electronic device. It is to be appreciated that any of the embodiments of the apparatus disclosed herein may also be designed to display any number of electronic devices, such as one, two, three, four, or more electronic devices.

As previously mentioned, the apparatus is typically designed to securely display a particular type of electronic device. For instance, some embodiments of the apparatus are designed to securely display a smartphone (such as the embodiments depicted at least in FIGS. 15-24), while other embodiments of the apparatus are designed to securely display a tablet computer (such as the embodiments shown at least in FIGS. 1-13 and 25-27). It is to be appreciated, however, that any embodiment of the apparatus may be re-designed so that the apparatus can securely display another type of electronic device. For example, an embodiment of the apparatus designed to securely display a smartphone may be re-designed to securely display a cellular phone. In another example, an embodiment of the apparatus designed to securely display a tablet computer may be re-designed to display an mp3 player. Further, the embodiments of the apparatus shown and described below may be re-designed to securely display different brands of a particular type of electronic device. As an example, an apparatus designed to securely display an iPhone® may be re-designed to securely display a Droid Razr™ (available from Motorola Mobility Holdings, Inc. (Libertyville, Ill.)). As another example, an apparatus designed to securely display an iPad® may be re-designed to securely display a Kindle Fire® (available from Amazon.com (Seattle, Wash.)).

As used herein, an apparatus that securely displays an electronic device includes one that is designed to 1) display the electronic device and 2) securely retain the electronic device so that the electronic device cannot be easily removed from the apparatus. By securely displaying the electronic device, the apparatus reduces or even eliminates theft of the electronic device when the electronic device is displayed. In an example, the electronic device is securely displayed, for example, by encapsulating the electronic device in the apparatus. Removal of the electronic device typically entails at least partially disassembling the apparatus to release the electronic device. Typically, a tool, a key, or other suitable equipment or series of steps is required to at least partially disassemble the apparatus. As such, the likelihood of a theft is greatly reduced.

Referring now to the Figures, where like numerals indicate like or corresponding parts throughout the several views, an example of an assembly 10 is depicted in FIG. 1. The assembly 10 comprises an apparatus 100 for securely displaying an electronic device 12. As shown, the apparatus 100 is designed to securely display a tablet computer as the electronic device 12.

Details of the apparatus 100 are shown in FIGS. 2-7. The apparatus 100 comprises a support 102. In this embodiment, the support 102 has a stem 104 with an end 108 and a connector 106 coupled to the end 108. As shown, the stem 104 has a gooseneck configuration with a diameter D₁₀₄. Alternatively, the stem 104 may have other configurations, such as a curved configuration other than a gooseneck, a straight configuration, a bent configuration, and/or the like. Additionally, the diameter D₁₀₄ of the stem 104 may be larger or smaller than shown.

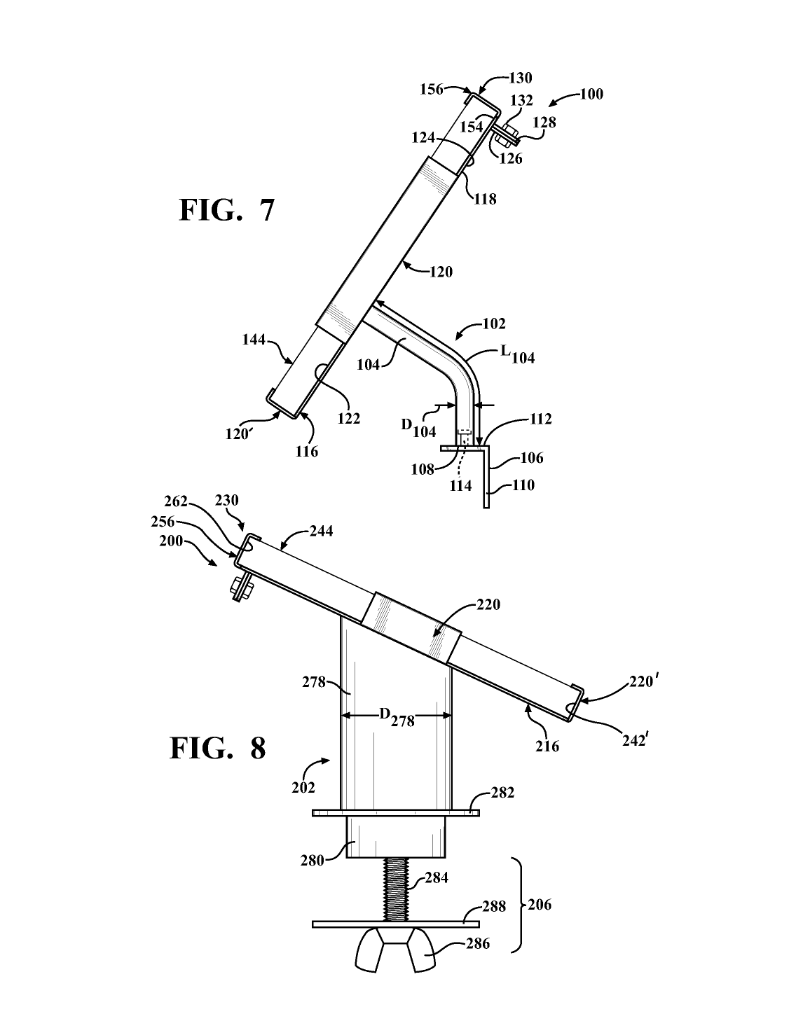

As best shown in FIG. 7, the stem 104 has a length L₁₀₄. Typically, the length L₁₀₄ of the stem 104 is selected based on a desirable display height of the electronic device 12. For example, the length L₁₀₄ of the stem 104 may be relatively short (such as from 4 to 8 inches) in instances where the apparatus 100 is coupled, attached, and/or connected to a table top. In another example, the length L₁₀₄ of the stem 104 may be relatively long (such as from 3 to 5 feet) in instances where the apparatus 100 is coupled, attached, and/or coupled to a floor.

The connector 106 couples, attaches, and/or connects the apparatus 100 to a surface (not shown) such as a counter top, a table top, or the like. In the present embodiment, the connector 106 is a bracket having two plates 110, 112 that are integrally coupled to one another at a pre-defined angle. As shown, the plates 110, 112 are coupled to one another at a right angle. With this configuration, the bracket may be coupled, attached, and/or connected to an edge of a table, where the plate 110 rests against a side table and the plate 112 rests against the top of the table. A fastener 114 may be used to couple the plate 110 and/or 112 to the surface. As shown, the fastener 114 is a bolt, and the bolt may be disposed through an aperture (not shown) in the plate 112 for coupling the plate 112 to the surface. Other fasteners 114 include screws, nails, etc. In some instances, an adhesive may also be used. While a bracket is shown, is to be appreciated that the connector 106 may otherwise be a plate, a brace, a clamp, or other suitable connector for coupling the apparatus 100 to the surface.

The apparatus 100 further comprises a frame 116 coupled to the support 102. In an example, the frame 116 is coupled to the support 102 at a pre-defined angle. As shown, the frame 116 is coupled to the support 102 at about a 65° angle. It is to be appreciated that the frame 116 may be coupled to the support 102 at a 45° angle, a 90° angle, a 180° angle, any other desirable angle. In an example, the frame 116 is integrally or metallugrically coupled to the support 102. In this example, the angle of the frame 116 is fixed. In another example, the frame 116 is mechanically coupled to the support 102. In this example, the angle of the frame 116 may be adjustable.

As shown in FIGS. 2-4, 6, and 7, the frame 116 has a frame base 118 and at least one retaining feature 120, 120′ coupled to the frame base 118 with at least one of the retaining features 120, 120′ and the frame 116 defining a frame slot 142, 142′. In an example, the retaining feature 120, 120′ is integrally coupled to the frame base 118. In another example, the retaining feature 120, 120′ is coupled to the frame base 118 mechanically (such as by using a fastener) or metallurgically (such as by welding).

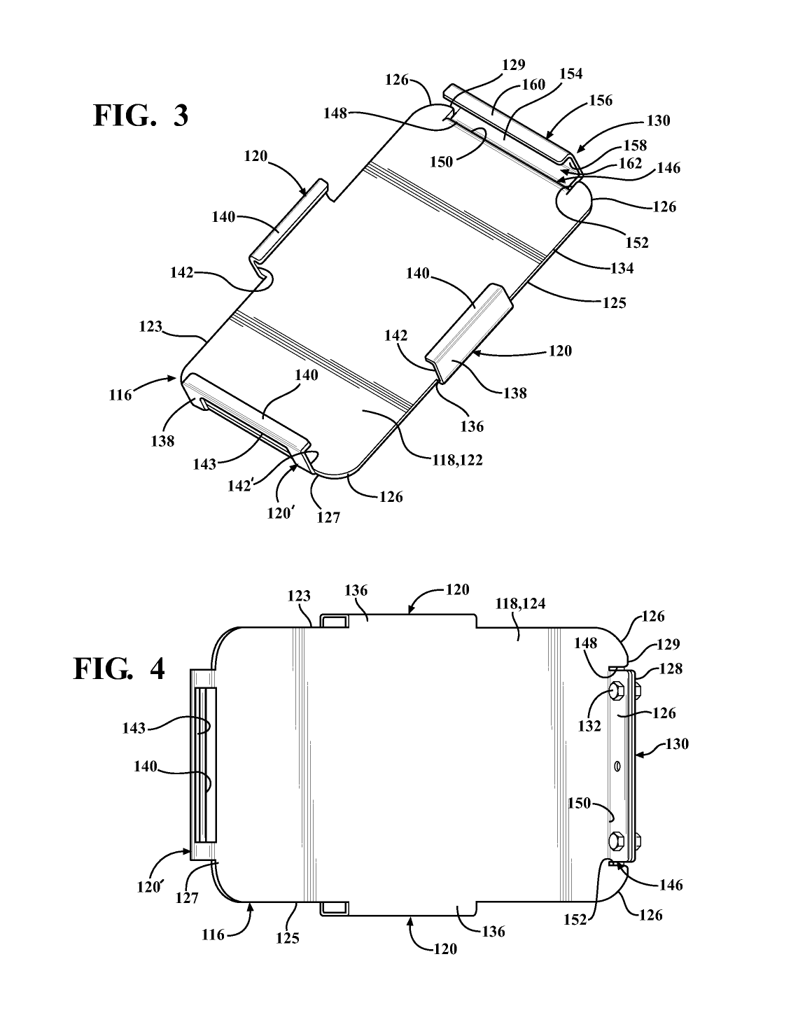

The frame base 118 has a flat surface and typically has at least the same surface area as the electronic device 12. It is to be appreciated, however, that the frame base 118 may have a surface area that is less or more than the surface area of the electronic device 12. As shown, the frame base 118 has a front surface 122 and a back surface 124. The frame base 118 further has a substantially rectangular shape with opposing sides 123, 125 and opposing ends 127, 129. Additionally, the frame base 118 may have rounded corners 126 (as shown in FIGS. 3 and 4), pointed corners, curved corners, or may be defined by a plurality of straight edges. The frame base 118 may otherwise have another shape, such as a circular shape, an oval shape, a polygonal shape, etc.

As shown in FIGS. 4 and 7, the frame 116 further comprises a flange 126, which may be coupled (such as integrally or metallurgically) to the back surface 124 of the frame base 118. As will be described in further detail below with reference to a method for securely displaying the electronic device 12, the frame 116 and a securing device 130 are mounted by aligning the flange 126 with a flange 128 coupled to the securing device 130, and then connecting or coupling the flanges 126, 128 together. The flanges 126, 128 may be connected together utilizing one or more fasteners 132 such as a bolt or a screw. In an example, the flanges 126, 128 each have three apertures, and fasteners 132 are used to couple the flanges 126, 128 in the first and third pair of apertures. The middle apertures of the flanges 126, 128 remain open for a padlock assembly. For example, the apertures not housing a fastener may receive a security clip and a padlock may be attached through the security clip and through the apertures. Further details of the securing device 130 are set forth below.

The frame base 118 further comprises an outer edge 134 with the retaining features 120, 120′ coupled to the frame base 118 at or about outer edge 134. In an example, the apparatus 100 includes a plurality of retaining features 120, 120′ spaced from one another. As shown, a retaining feature 120, 120′ is coupled to each of the side 123, the side 125, and the end 127. It is to be appreciated, however, that the frame 116 may have more than three retaining features 120, 120′. For instance, two or more retaining features 120, 120′ may be coupled to the frame base 118 at or about one or more of the side 123, the side 125, and the end 127. Additionally, the retaining features 120, 120′ each have a length L₁₂₀. and as shown, the length L₁₂₀ is the same for each of the retaining features 120, 120′. It is to be appreciated, however, that the length L₁₂₀ of one retaining feature 120, 120′ may be different from the length L₁₂₀ of anther retaining feature 120, 120′. Further, the length L₁₂₀ of the retaining features 120, 120′ may be longer (e.g. the retaining features 120, 120′ may extend across the entire side 123, 125 and across the entire end 127) or shorter (e.g. the retaining features 120, 120′ may be half the size as presently shown).

As previously mentioned, the frame 116 comprises a frame slot 142, 142′ defined by at least one of the retaining features 120, 120′ and the frame base 118. As shown, a retaining feature 120 is positioned on each of the sides 123, 125 of the frame base 118, and each of these retaining features 120 comprises a first retaining wall 136 coupled to the frame base 118, a second retaining wall 138 coupled to the first retaining wall 136, and a third retaining wall 140 coupled to the second retaining wall 138 with the first retaining wall 136, the second retaining wall 138, and the third retaining wall 140 defining a frame slot 142. As also shown, a retaining feature 120′ is positioned on the end 127 of the frame base 118. This retaining feature 120′ comprises a second retaining wall 138 coupled to the frame base 118 and a third retaining wall 140 coupled to the second retaining wall 138 with the second retaining wall 138, the third retaining wall 140, and the frame base 118 defining a frame slot 142′.

In an example, the retaining walls 136, 138, 140 forming the frame slot 142 may be integrally coupled to one another or may be metallurgically coupled to one another by welding or the like. Further, the retaining walls 138, 140 and the frame base 118 forming the frame slot 142′ may also be integrally coupled to one another or may be metallurgically coupled to one another by welding or the like. The frame slots 142, 142′ may also have any shape, such as a semi-square shape, a C-shape, or the like. Typically, the shape of the frame slots 142, 142′ conform to the shape of the portion of a case 144 that is inserted into the frame slots 142, 142′. The case 144 is described in further detail below.

In an example, one or more of the retaining features 120, 120′ have an opening 143 defined in the second retaining wall 138 for receiving at least one electrical connection line for the electrical device 12. Said differently, the opening 143 provides an access or entryway through the retaining feature 120, 120′ to the electronic device 12 at least for purposes of connecting electrical leads, wires, cords, and/or the like.

As shown in FIGS. 2-4, the end 129 of the frame base 118 defines a recessed portion 146 having edges 148, 150, 152. The securing device 130 is partially disposed in the recessed portion 146 when the securing base 154 is mounted to the frame 116. Further, the recessed portion 146 guides the securing device 130 into proper position when mounting the securing device 130 with the frame 116.

Details of the securing device 130 will now be described. The securing device 130 is removably coupled to the frame 116 and has the securing base 154 and a locking feature 156 selectively mounted to the securing base 154. In this embodiment, the locking feature 156 is spaced from the retaining features 120, 120′. The locking feature 156 at least partially defines a securing slot 162. For instance, the locking feature 156 comprises a first locking wall 158 coupled to the securing base 154 and a second locking wall 160 coupled to the first locking wall 158 with the first locking wall 158, the second locking wall 160, and the securing base 154 defining a securing slot 162.

As previously mentioned, the securing device 130 further comprises a flange 128 coupled to securing base 154 and is configured to be connected to the flange 126 of the frame base 118. In an example, the flange 128 is integrally coupled to the securing base 154. In another example, the flange 128 is metallurgically coupled to the securing base 154 by welding or the like. When the securing device 130 is coupled to the frame 116, the flanges 126, 128 are aligned and one or more of the fasteners 132 are utilized to connect the flanges 126, 128 together. In the embodiment shown, the flanges 126, 128 have one or more apertures (not shown) where respective apertures are aligned for receiving a fastener 132, such as a bolt or screw. The fastener(s) 132 may be removed when the securing device 130 is removed from the frame 116.

It is to be appreciated that when the frame 116 and the securing device 130 are mounted, the frame slot 142, 142′ and the securing slot 162 cooperate to securely retain the case 144 to the frame 116. In this way, the apparatus 100 reduces or even prevents theft of the electronic device 12.

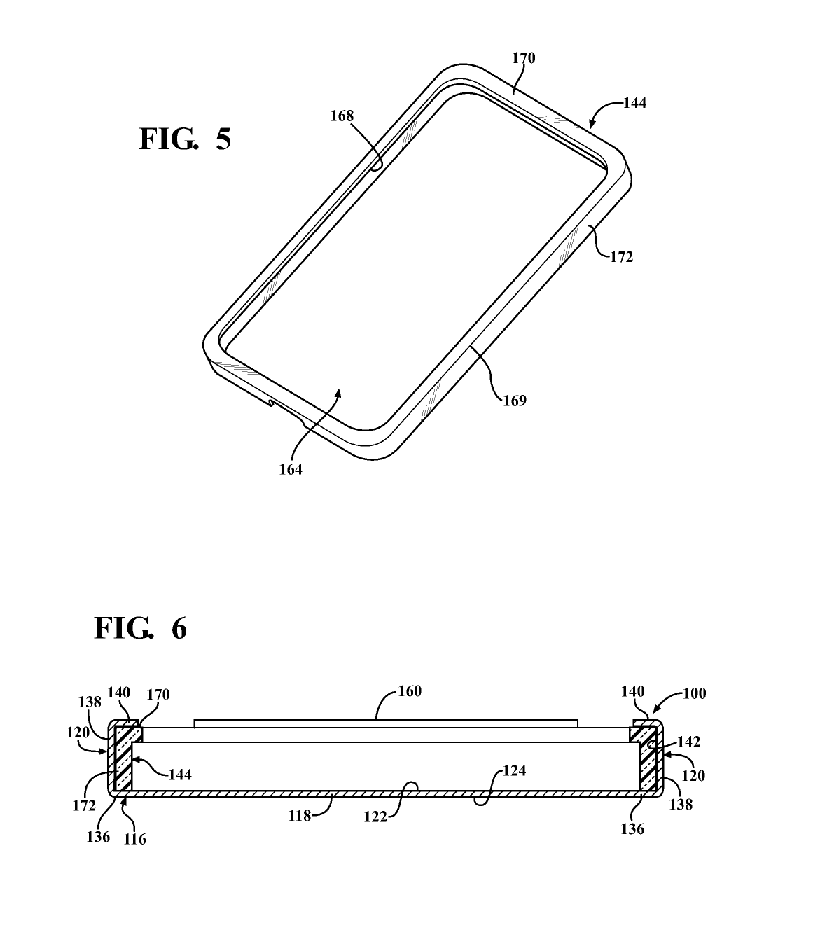

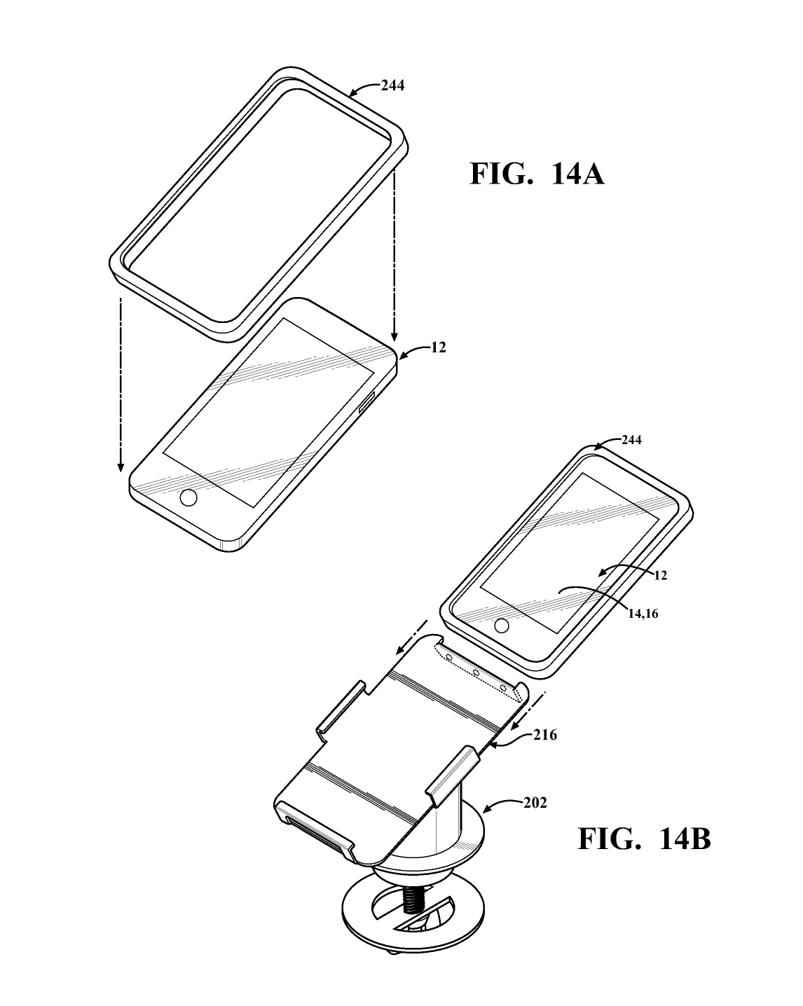

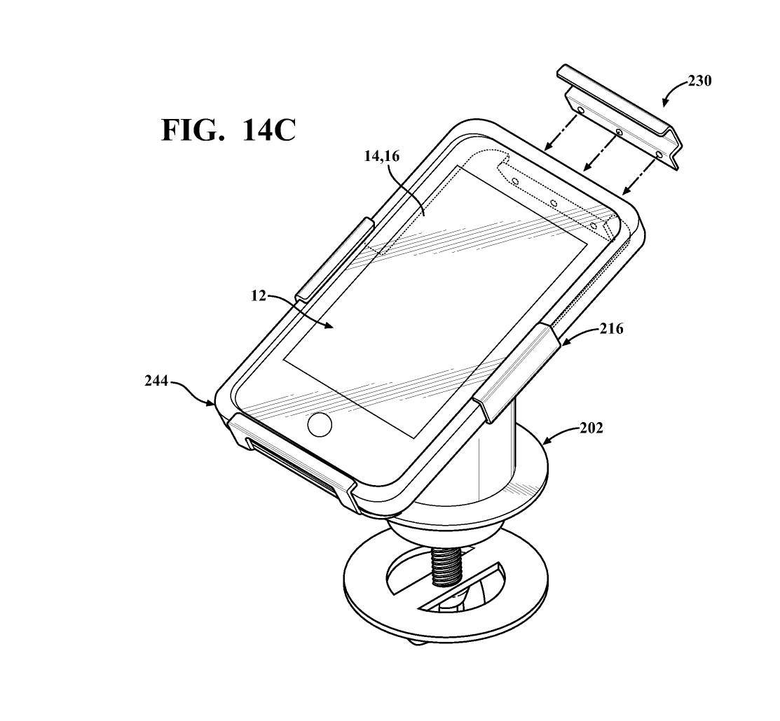

Referring to FIGS. 1 and 5, the case 144 is formed of a polymeric material, such as a polyacrylic, and may be formed utilizing a suitable forming process such as molding. The case 144 has an opening 164 for at least partially encapsulating the electronic device 12 while permitting the face 14 at the front 16 of the device 12 to be exposed through the opening 164. The case 144 comprises a top 170 with an inner edge 168 and an outer edge 169 and at least one side 172 coupled to the top 170 about the outer edge 169. The inner edge 168 defines the opening 164. The case 144 further comprises at least one side 172 which is integrally coupled to the top 170. As shown, the side 172 is integrally coupled to the top 170 at about a right angle, and the top 170 and side 172 define the opening 164 for receiving the electronic device 12. With this configuration, and as shown in FIG. 14A, the case 144, which does not have a bottom, is placed over the front 16 and sides 17 of the electronic device 12 such that the electronic device 12 is disposed inside the opening 164 with the face 14 and a back (not shown) of the device 12 exposed through the opening 164. Further, the top 170 of the case 144 covers a portion of the front 16 of the electronic device 12 and frames the face 14 of the electronic device 12. This is shown in FIGS. 1 and 14B. By framing the face 14 of the electronic device 12, the face 14 remains exposed or uncovered so that potential customers can touch and use the electronic device 12 while the device 12 is securely displayed in the apparatus 100.

In an example, the case 144 includes at least one recess 175 defined in the side 172, and the recess 175 of the case 144 is aligned with the opening 143 of the retaining feature 120, 120′ when the case 144 is disposed in the frame slots 142, 142′. Alignment of the recess 175 and the opening 143 provides access or an entryway through the retaining feature 120, 120′ and the case 144 to the electronic device 12 for electrical leads, wires, cords, etc.

In an example, the case 144 may be completely transparent, partially transparent, or translucent. Additionally, the case 144 may be colorless, or may be tinted to impart a desired color or tint to the case 144. In this example, light can at least partially pass through the case 144. In another example, the case 144 may be opaque such that no light can pass through the case 144.

The apparatus 100 described above is used in the assembly 10 to securely display the electronic device 12. In an example, the assembly 10 comprises the support 102, the frame 116, the securing device 130 removably coupled to the frame 116, the electronic device 12, and the case 144 having the opening 164 with the electronic device 12 at least partially encapsulated by the case 144 and securely retained within the case 144. The face 14 of the electronic device 12 is exposed through the opening. Furthermore, the electronic device 12 is secured to the frame 116 when the case 144 is disposed within the frame slot 142, 142′ and the securing slot 162.

Another embodiment of the apparatus 200 is shown in FIG. 8. In this embodiment, the apparatus 200 comprises a support 202, a frame 216 coupled to the support 202 with at least one retaining feature 220, 220′ at least partially defining a frame slot 242, 242′, a securing device 230 removably coupled to the frame 216 and having a locking feature 256 with a securing slot 262, and a case 244 at least partially encapsulating the electronic device 12. The frame 216, the securing device 230, and the case 244 of the apparatus 200 are the same as the frame 116, the securing device 130, and the case 144 of the apparatus 100. The support 202 of the apparatus 200, however, has a different configuration than the support 102 of the apparatus 100. The support 202 has a first section 278 which is coupled to the frame 216, a second section 280 which is coupled to the first section 278, a flange 282 disposed between the first 278 and second 280 sections, and a third section 284 which is coupled to the second section 280. As shown, the first section 278 has a diameter D₂₇₈. It is to be appreciated that the diameter D₂₇₈ may have any diameter, which may be larger or smaller than the diameter D₂₇₈ shown in FIG. 8. Additionally, the first section 278 may have any desired length and shape. As shown, the first section 278 is round. Other shapes of the first section 278 may include oval shapes, square shapes, rectangular shapes, triangular shapes, pentagonal shapes, etc. Additionally, the first section 278 is shown as having a smooth surface. However, the first section 278 may alternatively have a surface that is textured and/or designed.

The support 202 is generally designed to be coupled, attached, and/or connected to a surface, such as a table top, a counter top, or the like. For the embodiment shown in FIG. 8, the second section 280 of the support 202 is configured to be introduced into an aperture formed in the surface, and the flange 282 abuts the surface when the second section 280 is disposed in the aperture. While the second portion 280 may have any desirable shape, the second section 280 is typically small enough to fit through the aperture formed in the surface.

As shown, the third section 284 is threaded and is configured to receive a wing nut 286 and washer 288, which together constitute a connector 206. The third section 284 receives the wing nut 286 and washer 288 underneath the surface, where the wing nut 286 is tightened with the washer 288 abutting the underside of the surface to secure the apparatus 200 to the surface. It is to be appreciated that the third section 284 may have an alternative configuration, such as a post with a plate having fasteners or clamps for securing the support 202 to the surface.

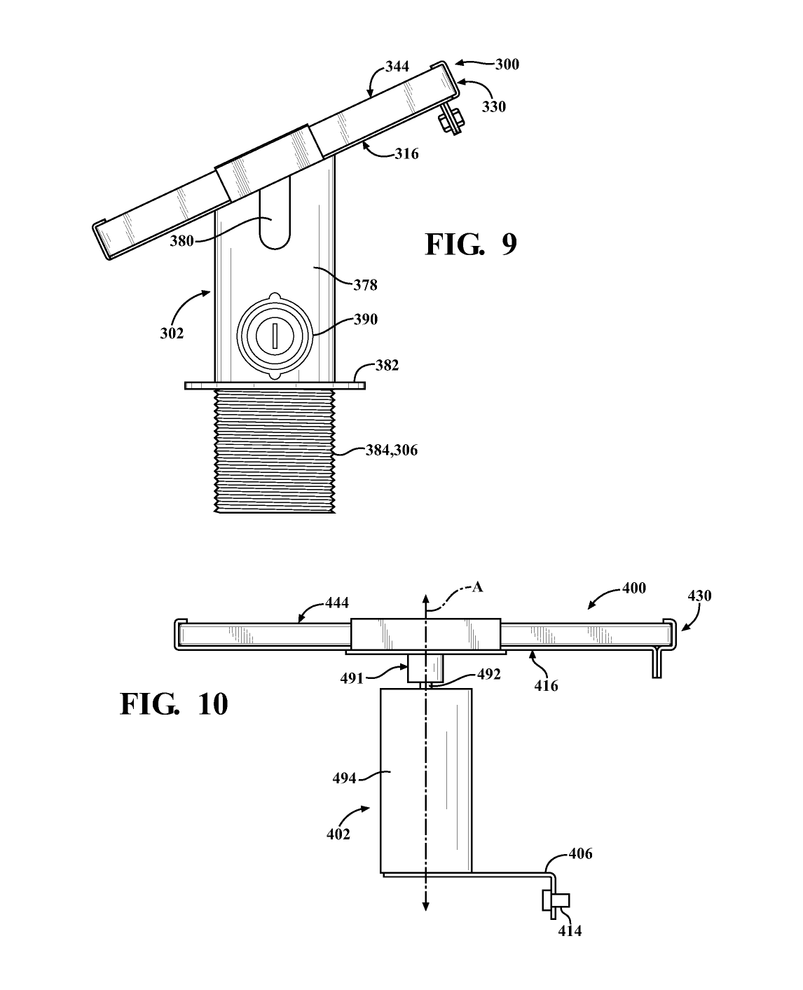

Another embodiment of the apparatus 300 is shown in FIG. 9. The apparatus 300 comprises a support 302, a frame 316 coupled to the support 302, a securing device 330 removably coupled to the frame 316, and a case 344 for at least partially encapsulating the electronic device 12. The frame 316, the securing device 330, and the case 344 of the apparatus 300 are the same as those of the apparatus 100 and 200 described above. However, in this embodiment, the support 302 comprises a first section 378 that is removably coupled to a second section 380, and a third section 384 with a flange 382 disposed between the first 378 and third 384 sections. The second section 380 is coupled to the frame 380. The first section 378 is not coupled to the frame 316 so that the second section 380 can be removed from the first section 378.

As shown, the support 302 further comprises a locking mechanism 390 for locking the first 378 and second 380 sections together. In an example, the first section 378 is hollow, and the second section 380 slides into and out of the hollow first section 378. When assembled together, the first 378 and second 380 sections may be locked together utilizing the locking mechanism 390. Assembly of the first 378 and second 380 sections may be desirable when the electronic device 12 is being displayed. When disassembled, the first 378 and second 380 sections may be unlocked so that the second section 380 with the electronic device 12 may be removed. Disassembly may be desirable when the electronic device 12 is not being displayed (such as when the electronic device is being stored).

Further, the third section 384, which is the connector 306, couples with a surface, such as a table top. As shown, the third section 384 is threaded and is designed to be coupled with a threaded aperture formed in the surface. Alternative configurations of the third section 384 may also be utilized so long as the third section 384 suitably couples to the surface.

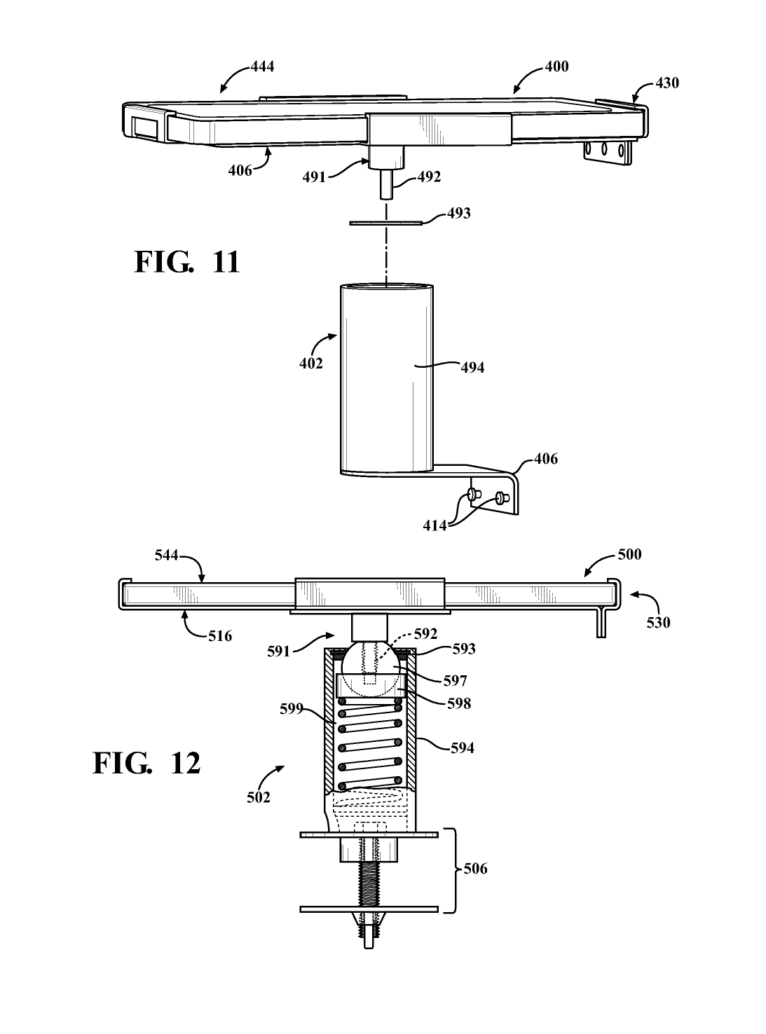

FIGS. 10 and 11 illustrate another embodiment of the apparatus 400. In this embodiment, the apparatus 400 comprises a support 402, a frame 416 coupled to the support 402, a securing device 430 removably coupled to the frame 416, and a case 444 for at least partially encapsulating the electronic device 12. The frame 416, the securing device 430, and the case 444 of the apparatus 400 are the same as those of the apparatuses 100, 200, and 300 described above. In this embodiment, the support 402 comprises a swivel mechanism 491 with a post 492 coupled to a washer 493 which is disposed in a hollow stem 494. The swivel mechanism has an axis A of rotation, and the swivel mechanism 491 enables the frame 416 to rotate about the axis A. In this way, the frame 416 can be rotated to display the electronic device 12 in a vertical orientation, a horizontal orientation, and in orientations between vertical and horizontal. The support 402 further comprises a connector 406, which as shown in FIGS. 10 and 11 is a bracket with a fastener 414. It is to be appreciated that other configurations of the connector 406 may also be used.

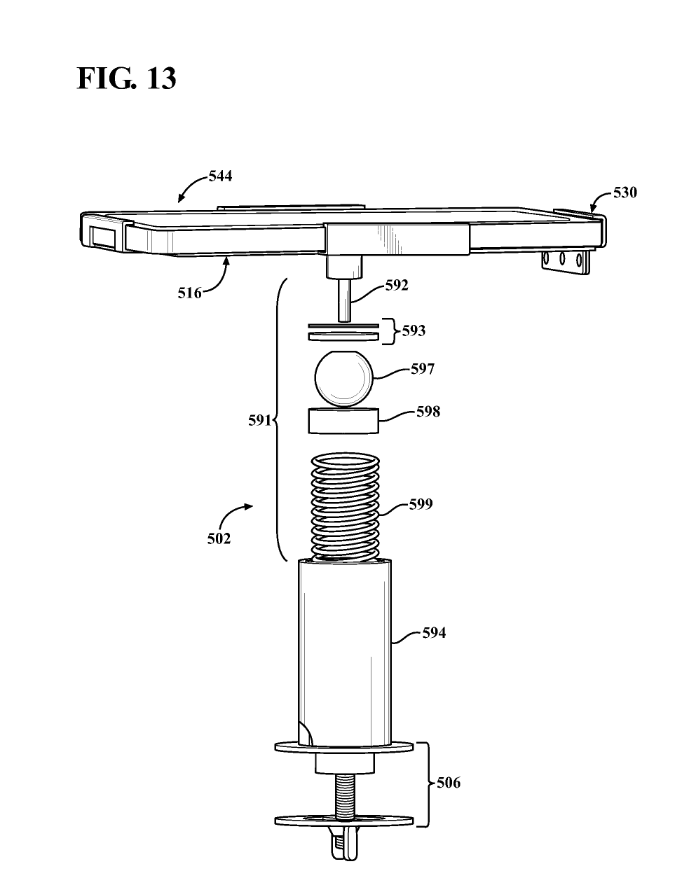

Referring now to FIGS. 12 and 13, still another embodiment of the apparatus 500 comprises a support 502, a frame 516 coupled to the support 502, a securing device 530 removably coupled to the frame 516, and a case 544 for at least partially encapsulating the electronic device 12. The frame 516, the securing device 530, and the case 544 of the apparatus 500 are the same as those of the apparatuses 100, 200, 300, and 400 described above. In this embodiment, the support 502 is designed to enable movement of the frame 516 displaying the electronic device 12 in a plurality of directions. For instance, the frame 516 may be moved forwards, backwards, from side-to-side, rotated at least between vertical and horizontal orientations, etc. As shown, the support 502 comprises a ball-and-socket mechanism 591 with a post 592 coupled to a washer 593, where the post 592 and the washer 593 are disposed in a hollow stem 594. Also disposed inside the hollow stem 594 is a ball 597 removably supported by a socket 598, and the socket 598 is supported on a spring 599. In an example, the ball 597 and socket 598 arrangement enables the frame 516 to move in a number of the different directions. Additionally, the support 502 comprises a connector 506 for coupling the support 502 to a surface such as a table top. As shown, the connector 506 is similar to the support 202 shown and described above with reference to FIG. 8.

An example of a method for displaying the electronic device 12 will now be described. For illustrative purposes, the method will be described utilizing the apparatus 200. With reference to FIGS. 14A-14C, the method comprises the steps of at least partially encapsulating the electronic device 12 in the case 244. As shown in FIG. 14A, the electronic device 12 is disposed in the opening 164 of the case 244. This is accomplished by placing the case 244 over the front 16 of the electronic device 12 so that the top 170 of the case 144 covers a portion of the front 16 of the electronic device 12 and frames the face 14 of the electronic device 12. Then, as shown in FIG. 14B, the method comprises inserting a first portion of the case 244 with the electronic device 12 into the frame slots 120, 120′. In an example, inserting may be accomplished by sliding the case 244 with the electronic device 12 along the front surface 122 of the frame 118 and into the slots 142, 142′. As shown in FIG. 14C, the method further comprises positioning the securing device 230 about the case 244 such that a second portion of the case 244 with the electronic device 12 is disposed within the securing slot 262, and coupling the securing device 230 to the frame 216. As previously described, coupling of the securing device 230 to the frame 216 may be accomplished by coupling the flange 126 connected to the frame 216 with the flange 228 connected to the securing device 230 via a fastener or the like.

Other embodiments of the apparatus 600, 700, 800, 900, 1000, 1100 will now be described with reference to FIGS. 15-24. In these embodiments, the apparatus 600, 700, 800, 900, 1000, 1100 is designed to securely display a smartphone.

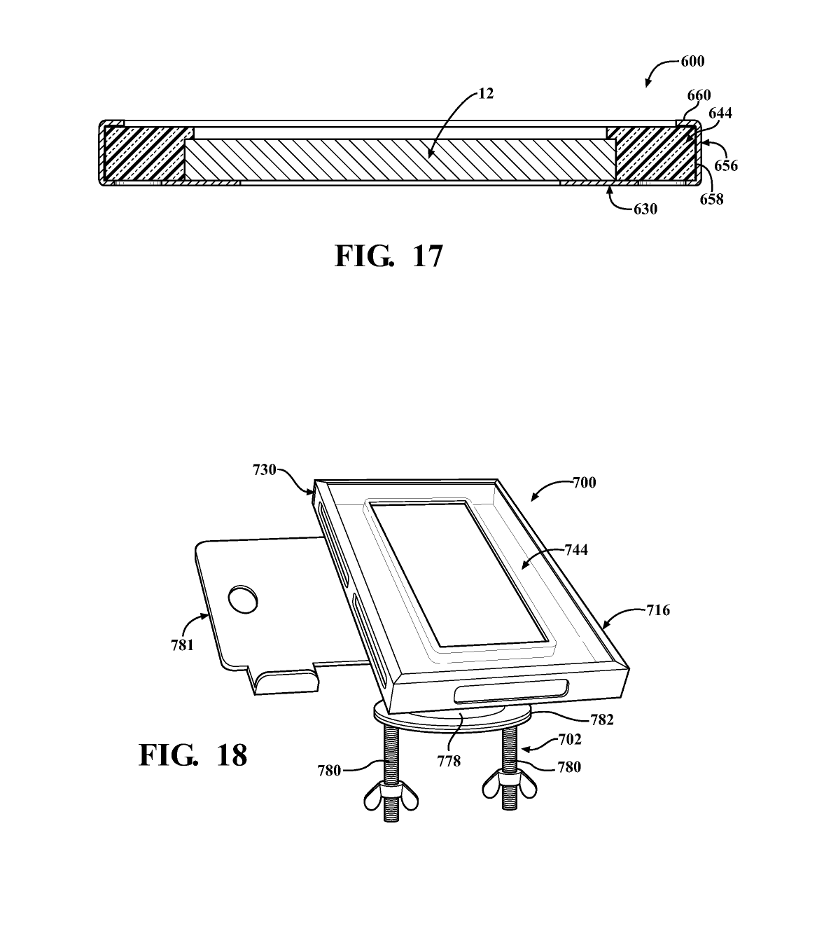

Referring to FIGS. 15-17, an embodiment of the apparatus 600 is designed to display two electronic devices 12, 22. In FIG. 17, the electronic device 12 is schematically shown. The apparatus 600 comprises a support 602, a frame 616 coupled to the support 602, a securing device 630 removably coupled to the frame 616, and a case 644 for at least partially encapsulating the electronic device 12. The apparatus 600 further comprises a saddle 681 for receiving and displaying the second electronic device 22.

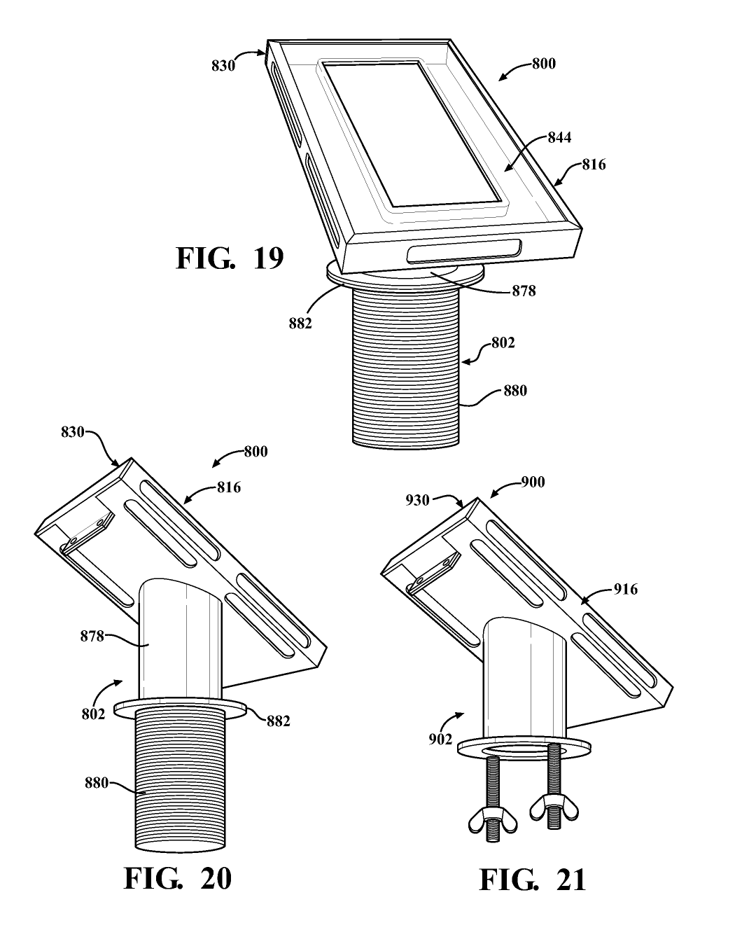

The support 602 has the same design as the support 802 of the apparatus 800 shown in FIGS. 19 and 20, which will be described in detail below.

The frame 616 may be integrally or metallurgically coupled to the support 602. In this embodiment, the frame 616 has a frame base 618 having a flat surface that has the same surface area as the case 644. As shown in FIG. 16, the frame base 618 comprises at least one flange 626, which may be integrally or metallurgically coupled to a back surface 624 of the frame base 618. The frame 616 further comprises a retaining feature 620 coupled to or about an outer edge 634 of the frame base 618. As shown, the retaining feature 620 is positioned along the entire length of the outer edge 634 and terminates at two ends 635, 637 of the outer edge 634. The retaining feature 620 comprises a second retaining wall 638 coupled to the frame base 618 and a third retaining wall 640 coupled to the second retaining wall 638 with the second retaining wall 638, the third retaining wall 640, and the frame base 618 collectively defining a frame slot 642. In an example, the retaining walls 638, 640 and the frame base 618 forming the frame slot 642 may be integrally coupled to one another or metallurgically coupled to one another. Additionally, the frame slot 642 may have any shape, such as a semi-square shape, a C-shape, or the like. Typically, the frame slot 642 conforms to the shape of the portion of the case 644 that is inserted into the frame slot 642.

In an example, the retaining feature 620 has one or more openings 643 defined in the second wall 638 and/or the frame base 618 has one or more openings 643 formed in the frame base 618. The openings 643 provide an access or entryway through the retaining feature 620 and/or the frame base 816 to the electronic device 12 for connecting electrical leads, wires, cored, and/or the like.

The securing device 630 is removably coupled to the frame 616 and has a securing base 654 and a locking feature 656 mounted to the securing base 654. The locking feature 656 is mounted to or about an outer edge 657 of the securing base 654. As shown, the locking feature 656 is positioned along the entire length of the outer edge 657 and terminates at two ends 659, 661 of the outer edge 634. The locking feature 656 comprises a first locking wall 658, coupled to the securing base 654 and a second locking wall 660 coupled to the first locking wall 658 with the first locking wall 658, the second locking wall 660, and the securing base 654 defining a securing slot 662. In an example, the locking walls 658, 660 and the securing base 654 forming the securing slot 662 may be integrally or metallurgically coupled to one another. Additionally, the securing slot 662 may have any shape, such as a semi-square shape, a C-shape, or the like. Typically, the securing slot 662 conforms to the shape of the portion of the case 644 that is inserted into the securing slot 662.

In an example, the securing device 630 may have one or more access openings (not shown) defined in the second locking wall 658 and/or the securing base 654 may have one or more openings 643 formed in the securing base 654. The openings 643 provide access through the locking feature 630 and/or the securing base 654 to the electronic device 12 for connecting electrical leads, wires, cored, and/or the like.

The securing device 630 further comprises at least one flange 628, which may be integrally or metallurgically coupled to a back surface 653 of the securing base 654. The flange(s) 628 are positioned so that when the securing device 130 is coupled to the frame 116, the flange(s) 128 are aligned with the flange(s) 626, and one or more of the fasteners 132 may be utilized to connect the flanges 626, 628 together. In the embodiment shown, the flanges 626, 628 have an aperture for receiving a fastener. The fastener may be removed when the securing device 630 is removed from the frame 616.

As shown, the frame 616 and the securing device 630 have rounded outer edges 634, 657, respectively. When coupled together, the end 635 of the retaining feature 630 abuts the end 659 of the locking feature 656 and the end 637 of the retaining feature abuts the end 661 of the locking feature to form a combined part having a circular or oval shape. Further, when the frame 616 and the securing device 630 are coupled together, the frame slot 642 is joined to the securing slot 662 to form a single, continuous slot. It is to be understood that the outer edges 634, 657 may have other shapes forming a differently shaped part. For instance, and as shown in the embodiment of the apparatus 800 depicted in FIG. 19, frame 816 and the securing device 830, when coupled, form a combined part having a rectangular shape. Further details of the apparatus 800 are described below.

Referring back to FIGS. 15 and 16, the case 644 is shaped to conform to the shape of the continuous slot of the combined part formed by coupling the frame 616 and the securing device 630 together. As shown, the case 644 is oval-shaped. The case 644 may be formed of a polymeric material, such as a polyacrylic, and may be formed utilizing a suitable forming process such as molding. The case 644 has an opening 664 for at least partially encapsulating the electronic device 12 while permitting the face 14 at the front 16 of the device 12 to be exposed through the opening 664. The case 644 comprises a top 670 having an inner edge 668 which defines the opening 664. The case 644 further comprises a side 672 which is integrally coupled to the top 670. As shown, the side 672 is integrally coupled to the top 670 at about a right angle, and the top 670 and side 672 define the opening 664 for receiving the electronic device 12. With this configuration, the case 144, which does not have a bottom, is placed over the front 16 and sides 17 of the electronic device 12 such that the electronic device 12 is disposed inside the opening 664 with the face 14 and a back (not shown) of the device 12 exposed through the opening 664. Further, the top 670 of the case 644 covers a portion of the front 16 of the electronic device 12 and frames the face 14 of the electronic device 12. This is shown in FIG. 15. By framing the face 14 of the electronic device 12, the face 14 remains exposed or uncovered so that potential customers can touch and use the electronic device 12 while the device 12 is securely displayed in the apparatus 600.

In an example, the case 644 includes at least one recess 675 defined in the side 672 and through the case 644 and is aligned with an opening 643 defined in the retaining feature 620 and/or the frame base 618. Alignment of the opening 643 and the recess 675 provides access or an entryway through the retaining feature 620 and the case 644 to the electronic device 12 for electrical leads, wires, cords, etc.

The case 644 may be completely transparent, partially transparent, or translucent. Additionally, the case 644 may be colorless, or may be tinted to impart a desired color or tint to the case 644. In this example, light can at least partially pass through the case 644. In another example, the case 644 may be opaque such that no light can pass through the case 644.

In instances where the case 644 is completely transparent, partially transparent, or translucent, the apparatus 100 may further comprise an illumination feature 676 for illuminating portion(s) of the case 644. The illumination feature 676 is schematically depicted in FIG. 16 as being coupled to the frame base 618 as well as disposed in the case 644. It is to be appreciated that the illumination feature 676 may be coupled to other areas of the frame 616, in the case 644, or on the support 602. As one example, the illumination feature 676 is a ribbon including a plurality of LED's disposed and/or arranged on the frame 616 so that desired portions of the case 644 illuminate. In another example, the illumination feature 676 is a ribbon including a plurality of LED's disposed and/or arranged in the case 644 so that desired portions of the case 644 illuminate. For instance, the LED's may be arranged so that the periphery of the opening 664 of the case 644 illuminates. With this configuration, the LED's would illuminate the periphery of the electronic device 12.

The apparatus 600 further comprises a saddle 681 coupled to a back side 624 of the frame base 618 and/or a back side 653 of the securing base 654 utilizing a fastener, such as a bolt, a screw, a clamp, etc. The saddle 681 includes a saddle base 683 with a shelf 685 coupled at a bottom edge 687 of the saddle base 683. The second electronic device 22 may be placed on the saddle base 683 and supported by the shelf 685.

Another embodiment of the apparatus 700 is shown in FIG. 18. In this embodiment, the apparatus 700 comprises a support 702, a frame 716 coupled to the support 702 with at least one retaining feature 720 at least partially defining a frame slot 742, a securing device 730 removably coupled to the frame 716 and having a locking feature 756 with a securing slot 762, and a case 744 at least partially encapsulating the electronic device 12. The apparatus 700 also comprises a saddle 781 for displaying a second electronic device. The frame 716, the securing device 730, and the case 744 of the apparatus 700 are the same as the frame 616, the securing device 630, and the case 644 of the apparatus 600 except that the combination of the frame 716 and the securing device 730 forms a part with a rectangular shape. Further, the case 744 has a rectangular shape that conforms to the part formed by the combination of the frame 716 and the securing device 730.

The support 702 of the apparatus 700, however, has a different configuration than the support 602 of the apparatus 600. The support 702 has a first section 278 which is coupled to the frame 216, a plurality of second sections 780 coupled to the first section 778, and a flange 782 disposed between the first 778 and second 780 sections. The first section 778 may have any diameter and length as desired. As shown, the first section 778 is round. Other shapes of the first section 778 may include oval shapes, square shapes, rectangular shapes, triangular shapes, pentagonal shapes, etc. Additionally, the first section 778 is shown as having a smooth surface. However, the first section 778 may alternatively have a surface that is textured and/or designed.

The support 702 is generally designed to be coupled, attached, and/or connected to a surface, such as a table top, a counter top, or the like. For the embodiment shown in FIG. 18, the second sections 780 of the support 702 are introduced into respective apertures formed in the surface, and the flange 782 abuts the surface. While the second portions 780 may have any desirable shape, the second sections 780 are typically small enough to fit through the apertures formed in the surface.

Another embodiment of the apparatus 800 is shown in FIGS. 19 and 20. In this embodiment, the apparatus 800 comprises a support 802, a frame 816 coupled to the support 802, a securing device 830 removably coupled to the frame 816, and a case 844. In this embodiment, the apparatus 800 does not have a saddle, and is not designed to display a second electronic device. The frame 816, the securing device 830, and the case 844 of the apparatus 800 are the same as the frame 716, the securing device 730, and the case 744 of the apparatus 700 and forms a combined part with a rectangular shape. Further, the case 844 has a rectangular shape that conforms to the part formed by the combination of the frame 816 and the securing device 830.

In this embodiment, the support 802 comprises a first section 878 which is coupled to the frame 816, a second section 880 coupled to the first section 878 with a flange 882 disposed between the first 878 and second 880 sections. The first and second sections 878, 880 may have any diameter and length as desired. As shown, the first and second sections 878, 880 have the same diameter and substantially the same length, and both sections 878, 880 are round. Other shapes of the first 878 and second 880 sections may include oval shapes, square shapes, rectangular shapes, triangular shapes, pentagonal shapes, etc.

For the embodiment shown in FIGS. 19 and 20, the second section 880 is threaded and introduced into an aperture formed in the surface, and the flange 882 abuts the surface. While the second portion 880 may have any desirable shape, the second section 880 is typically small enough to fit through the aperture formed in the surface.

FIGS. 21 and 22 depict other embodiments of the apparatuses 900 and 1000, respectively. The apparatus 900 shown in FIG. 21 comprises a support 902, a frame 916, a securing device 930, and a case (not shown). The frame 916, the securing device 930, and the case of the apparatus 900 are the same as the frame 816, the securing device 830, and the case 844 of the apparatus 800 shown in FIGS. 19 and 20. Additionally, the support 902 has the same design as the support 702 for the apparatus 800 shown in FIG. 18. The apparatus 1000 shown in FIG. 22 has comprises a support 1002, a frame 1016, a securing device 1030, and a case (not shown). The frame 1016, the securing device 1030, and the case of the apparatus 1000 are also the same as the frame 816, the securing device 830, and the case 844 of the apparatus 800 shown in FIGS. 19 and 20. Additionally, the support 1002 has the same design as the support 102 for the apparatus 100 shown in FIGS. 1-7.

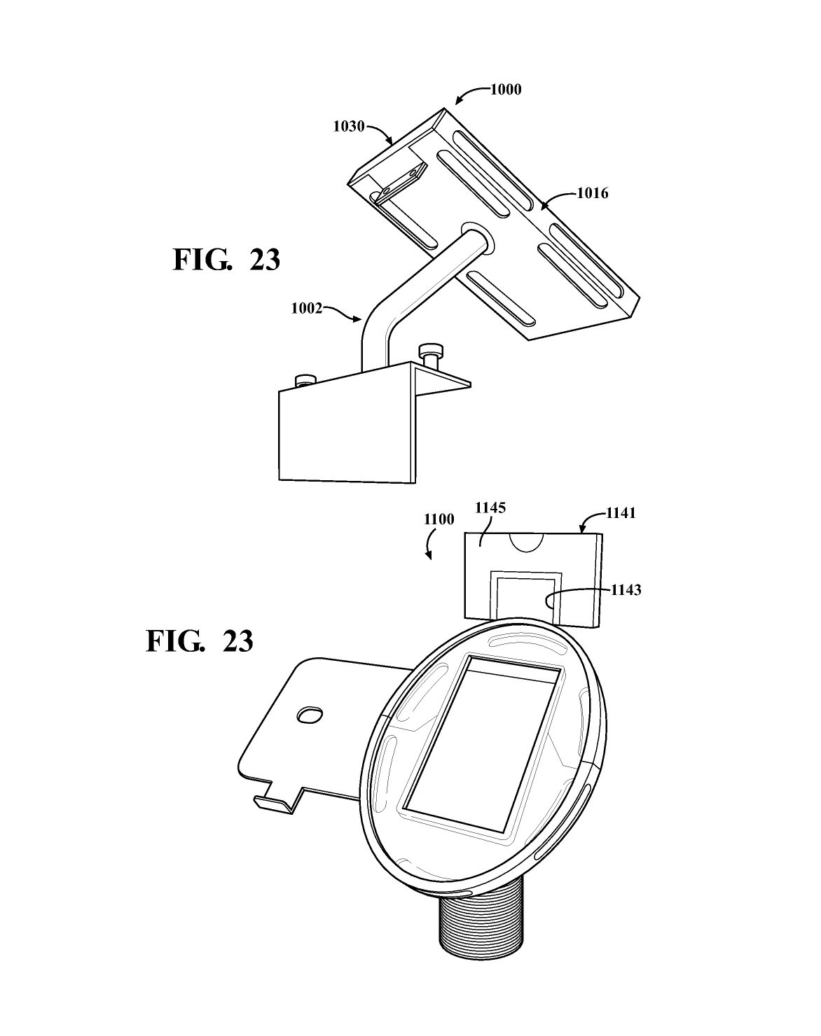

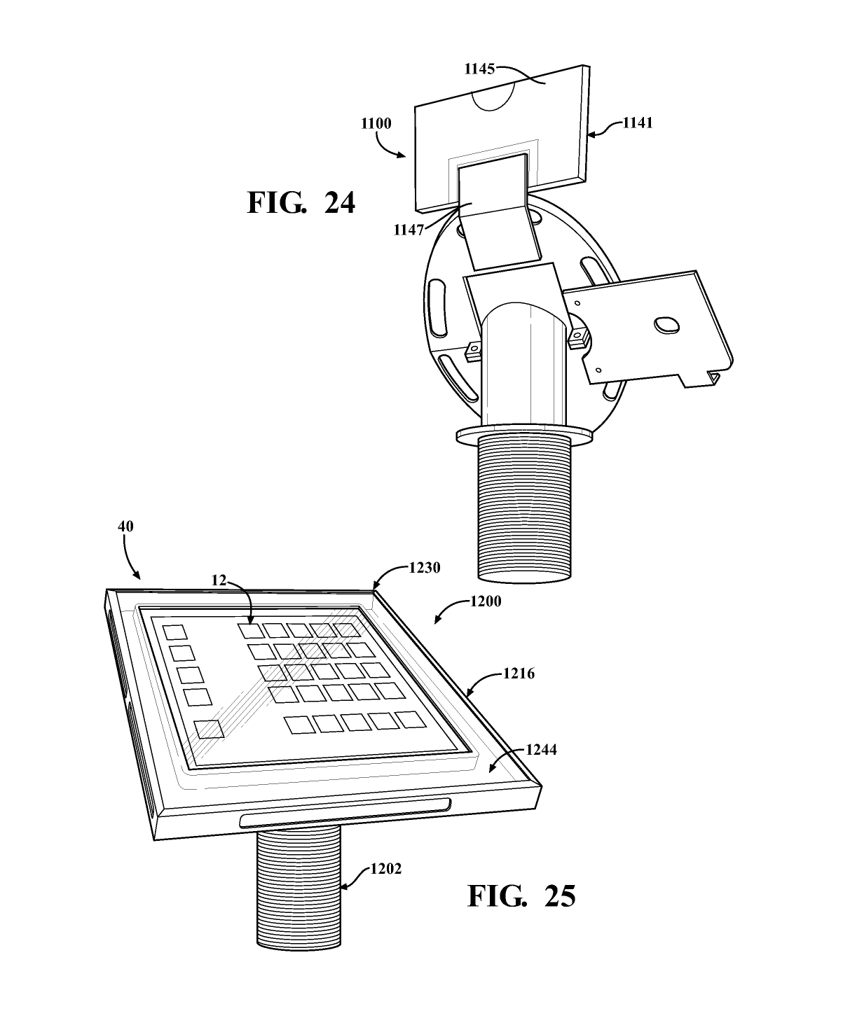

FIGS. 23 and 24 depict another embodiment of the apparatus 1100. The apparatus 1100 is the same as the apparatus 600 depicted in FIGS. 15-17 except that the apparatus 1100 further comprises a tag holder 1141. The tag holder 1141 is coupled to the securing device 1130 by an arm 1147 secured to the backside 1145 of the tag holder 1141. The tag holder 1141 is designed to hold a tag such as a price tag, an information tag, and/or the like. As shown, the tag holder 1141 includes a pocket 1143 within which the tag is placed.

Other embodiments of the apparatus 1200, 1300 are designed to securely display a tablet computer as the electronic device 12. FIG. 25 shows an assembly 40 including the apparatus 1200 and an electronic device 12. The apparatus 1200 is the same as the apparatus 800 shown in FIGS. 19 and 20 except that the frame 1216, the securing device 1230, and the case (not shown) are designed to fit a tablet computer rather than a smartphone. Further, the apparatus 1300 is the same as the apparatus 700 shown in FIG. 18 except that the apparatus 1300 does not have a saddle and the frame 1316, the securing device 1330, and the case (not shown) are designed to fit a tablet computer rather than a smartphone.

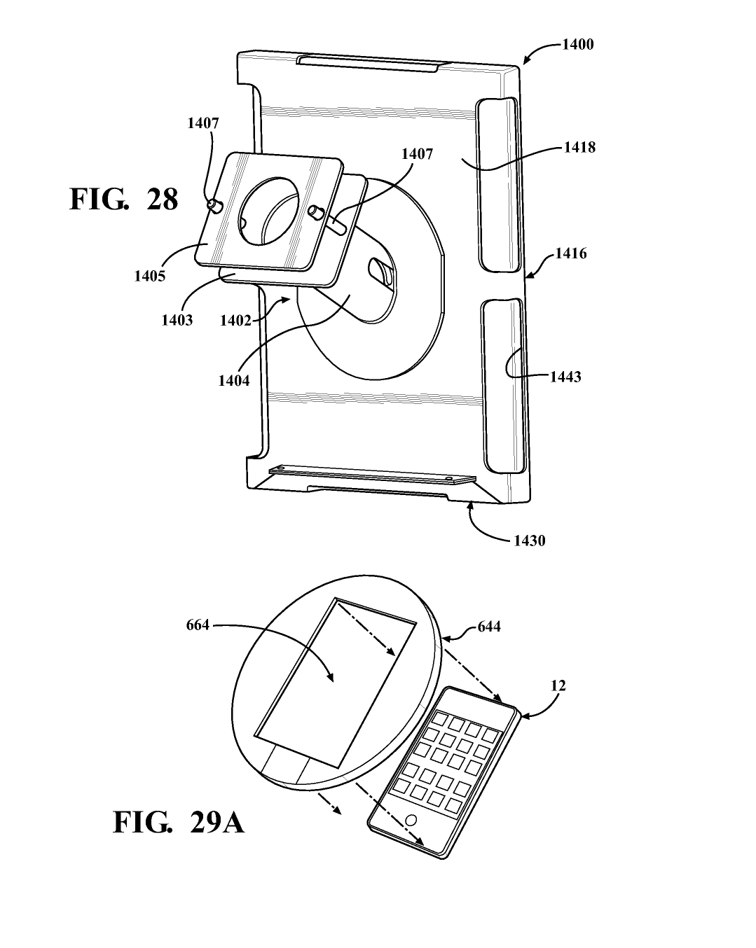

Yet another embodiment of the apparatus 1400 is depicted in FIG. 28. The apparatus 1400 includes a frame 1416, a securing device 1430, and a case (not shown) which are is very similar to the frame 616, the securing device 630, and the case 644 of the apparatus 600 except that the frame 1416 is rectangular-shaped. However, the frame 1416 of the apparatus 1400 has a plurality of openings 1443 which are formed in both the frame base 1418 and the retaining feature 1420. The openings 1443 are designed to receive electrical connection lines for the electrical device 12.

Additionally, the support 1402 of the apparatus 1400 is different. As shown, the support 1402 comprises a stem 1404 with top and bottom plates 1403, 1405 supported by posts 1407. When connected to a surface, the top plate 1403 rests against a top of the surface while the bottom plate 1405 rests against the back of the surface. The plates 1403, 1405 may be connected to the surface using a fastener, a clamp, or the like.

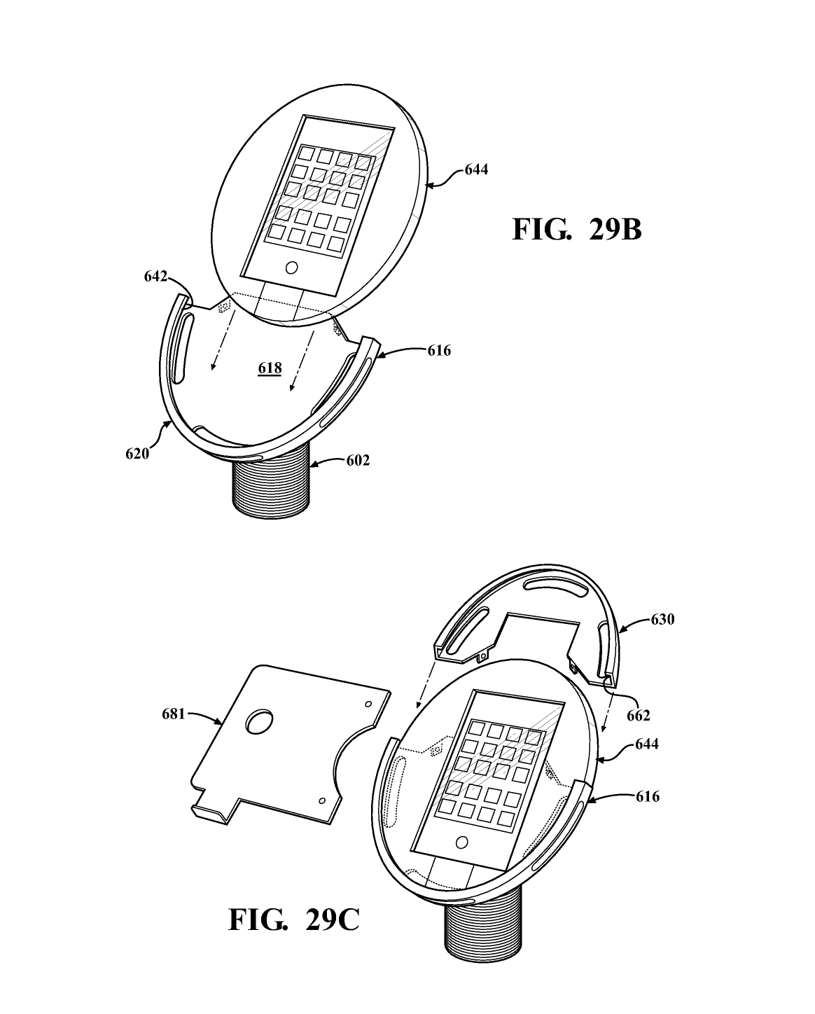

Another example of a method for displaying the electronic device 12 will now be described with reference to FIGS. 29A-29C. For illustrative purposes, the method will be described utilizing the apparatus 600. As shown in FIG. 29A, the electronic device 12 is disposed in the opening 664 of the case 644. This is accomplished by placing the case 644 over the front 16 of the electronic device 12 so that the top 670 of the case 644 covers a portion of the front 16 of the electronic device 12 and frames the face 14 of the electronic device 12. Then, as shown in FIG. 29B, the method comprises inserting a first portion of the case 644 with the electronic device 12 into the frame slot 642. In an example, inserting may be accomplished by sliding the case 644 with the electronic device 12 along the front surface 622 of the frame 618 and into the slot 642. As shown in FIG. 29C, the method further comprises positioning the securing device 630 about the case 644 such that a second portion of the case 644 with the electronic device 12 is disposed within the securing slot 662, and coupling the securing device 630 to the frame 616. As previously described, coupling of the securing device 630 to the frame 616 may be accomplished by coupling the flange 626 connected to the frame 616 with the flange 628 connected to the securing device 630 via a fastener or the like. As also shown in FIG. 29C, the saddle 681 is then coupled to the frame 618 and the securing device 630 utilizing a suitable fastener and the second electronic device 22 is positioned in the saddle.

Several embodiments of the apparatus 100, 200, 300, 400, 500, 600, 700, 800, 900, 1000, 1100, 1200, 1300, 1400 have been described above in conjunction with the figures. It is to be appreciated that the individual components of one apparatus 100, 200, 300, 400, 500, 600, 700, 800, 900, 1000, 1100, 1200, 1300, 1400 are interchangeable with one or more components of another apparatus 100, 200, 300, 400, 500, 600, 700, 800, 900, 1000, 1100, 1200, 1300, 1400. For instance, the apparatus 100 may be designed to utilize a case that is oval-shaped similar to the apparatus 600, or the apparatus 200 may be designed to utilize an illumination device similar to the apparatus 600. It is also to be appreciated that one or more of the components of the apparatuses 100, 200, 300, 400, 500, 600, 700, 800, 900, 1000, 1100, 1200, 1300, 1400 may be adjusted as needed. For instance, the dimensions of the component(s) may be adjusted based on the electronic device to be displayed, for example. As an example, the retaining and securing slots may be larger for a larger device.

The invention has been described in an illustrative manner, and it is to be understood that the terminology which has been used is intended to be in the nature of words of description rather than of limitation. It is now apparent to those skilled in the art that many modifications and variations of the present invention are possible in light of the above teachings. It is, therefore, to be understood that the invention may be practiced otherwise than as specifically described.

1. An apparatus for securely displaying an electronic device having a front with a face, said apparatus comprising:
a support;
a frame coupled to said support with said frame having a frame base and at least one retaining feature coupled to said frame base with at least one of said retaining feature and said frame base defining a frame slot;
a case formed of a polymeric material and having an opening for at least partially encapsulating the electronic device while permitting the face of the electronic device to be exposed through said opening; and
a securing device removably coupled to said frame with said securing device having a securing base and a locking feature selectively mounted to said securing base with said locking feature at least partially defining a securing slot, with said frame slot and said securing slot cooperating to securely retain said case to said frame for preventing theft of the electronic device.

2. The apparatus as set forth in claim 1 wherein said retaining feature has a first retaining wall coupled to said frame base and a second retaining wall coupled to said first retaining wall, with said first retaining wall, said second retaining wall, and said frame base collectively defining said frame slot.

3. The apparatus as set forth in claim 1 wherein said locking feature has a first locking wall coupled to said securing base, and a second locking wall coupled to said first locking wall, with said first locking wall, said second locking wall, and said securing base collectively defining said securing slot.

4. The apparatus as set forth in claim 1 wherein said case has a top with an inner edge and an outer edge and at least one side coupled to said top about said outer edge, and said inner edge of said top defining said opening.

5. The apparatus as set forth in claim 1 further comprising a plurality of retaining features spaced from one another with said locking feature of said securing device being spaced from said retaining features.

6. The apparatus as set forth in claim 1 wherein said frame has first and second opposing sides and first and second opposing ends, and wherein said at least one retaining feature further includes a plurality of retaining features with one of said retaining features coupled to said frame base at said first side, said second side, and said first end, and said securing device coupled to said frame base at said second end.

7. The apparatus as set forth in claim 1 wherein said frame base defines a recessed portion with said securing device being partially disposed in said recessed portion when said securing base is mounted to said frame.

8. The apparatus as set forth in claim 1 wherein said frame slot is defined by said frame base and said retaining feature and has first and second frame slot ends, and said securing slot is defined by said securing base and said locking mechanism and has first and second securing slot ends, with said first frame slot end being aligned with said first securing slot end and said second frame slot end being aligned with said second slot end for aligning said frame slot and said securing slot and forming a single continuous slot.

9. The apparatus as set forth in claim 1 wherein said retaining feature has at least one retaining wall with an opening defined in said retaining wall for receiving at least one electrical connection line for the electronic device.

10. The apparatus as set forth in claim 1 wherein each of said frame and said securing device has a flange with said flanges coupled together for coupling said frame and said securing device.

11. The apparatus as set forth in claim 10 wherein said flange of said frame is mounted to said frame base and said flange of said securing device is mounted to said securing base.

12. The apparatus as set forth in claim 1 wherein said support has a stem separated into first and second stem portions and a locking mechanism coupled to said stem portions for locking said stem portions together.

13. The apparatus as set forth in claim 1 wherein said support has a stem coupled to a swivel mechanism having an axis of rotation for rotating said frame about said axis.

14. The apparatus as set forth in claim 1 wherein said support has a stem coupled to a ball-and-socket mechanism for enabling movement of said frame in a plurality of directions relative to said stem.

15. The apparatus as set forth in claim 1 further comprising an illumination feature coupled to at least one of said frame and said case for illuminating at least a portion of said case.

16. The apparatus as set forth in claim 1 further comprising a saddle coupled to at least one of said frame and said securing device for display displaying a second electronic device.

17. A display assembly comprising:
a support;
a frame coupled to said support with said frame having a frame base and at least one retaining feature coupled to said frame base with at least one of said retaining feature and said frame base defining a frame slot;
a securing device removably coupled to said frame with said securing device having a securing base and a locking feature selectively mounted to said securing base with said locking feature at least partially defining a securing slot spaced from said frame slot;
an electronic device having a front with a face, a back, and a plurality of sides interconnecting said front and back; and
a case formed of a polymeric material and having an opening with said electronic device being at least partially encapsulated by said case and securely retained within said case with said face exposed through said opening, and said electronic device secured to said frame when said case is disposed within said frame slot and said securing slot.

18. A method of securely displaying an electronic device, the method utilizing an apparatus having a frame with a frame base and at least one retaining feature coupled to the frame base with at least one of the retaining feature and the frame base defining a frame slot, and the apparatus further having a case and a securing device removably coupled to the frame with the securing device having a securing base and a locking feature selectively mounted to the securing base with the locking feature at least partially defining a securing slot, wherein said method comprises the steps of:
at least partially encapsulating the electronic device in the case;
inserting a first portion of the case with the electronic device into the frame slot;
positioning the securing device about the case such that a second portion of the case with the electronic device is disposed within the securing slot; and
coupling the securing device to the frame.

19. The method as set forth in claim 18 wherein the apparatus further has an illumination feature and said method comprises the step of illuminating the case utilizing the illumination feature.

20. The method as set forth in claim 18 further comprising the steps of:
coupling a saddle to at least one of the frame and the securing device; and
positioning a second electronic device on the saddle.
